(19) United States
(12) Patent Application Publication
(10) Pub. No.: US 2026/0012152 A1
(43) Pub. Date: Jan. 8, 2026

(54) ANALOG CIRCUIT TO REDUCE RELATIVE INTENSITY NOISE

(71) Applicant: The Charles Stark Draper Laboratory, Inc., Cambridge, MA (US)

(72) Inventors: John DAVIS, Cambridge, MA (US); Eric HOLTZMAN, Cambridge, MA (US); William TRINKLE, Cambridge, MA (US); Timothy MCCARTHY, Cambridge, MA (US); Laura ANHALT, Cambridge, MA (US); David SMIRNOV, Cambridge, MA (US)

(73) Assignee: The Charles Stark Draper Laboratory, Inc., Cambridge, MA (US)

(21) Appl. No.: 19/067,117

(22) Filed: Feb. 28, 2025

Related U.S. Application Data
(60) Provisional application No. 63/559,098, filed on Feb. 28, 2024.

(51) Int. Cl. H03G 3/32; G01C 19/66; G01C 19/72

(52) U.S. Cl. CPC H03G 3/32; G01C 19/662; G01C 19/721; H03G 2201/103

(57) ABSTRACT

Systems and methods for reducing relative intensity noise are provided. The system can include a photodetector configured to detect the relative intensity noise of a light source. The system can include a transimpedance amplifier configured to provide a feedback loop with the photodetector to generate a first signal based on the detected relative intensity noise. The system can include a controller configured to actuate the light source based on the first signal to reduce the relative intensity noise. In this manner, the system can reduce the relative intensity noise of a light source for various optical systems, including gyroscopic systems.

### CROSS-REFERENCE TO RELATED APPLICATIONS

This application claims the benefit under 35 U.S.C. § 119 (e) of U.S. Provisional Application No. 63/559,098, filed Feb. 28, 2024.

### STATEMENT REGARDING FEDERALLY SPONSORED RESEARCH

None.

### TECHNICAL FIELD

Aspects of the disclosure generally relate to systems and methods for noise reduction. In particular, the concepts, systems and methods disclosed herein relate to reducing relative intensity noise of a light source using an analog disturbance rejection loop.

### BACKGROUND

Relative Intensity Noise (RIN) is a wideband noise inherent to light sources. RIN results in stochastic fluctuations in the intensity of optical power of a light signal generated by a light source and may be expressed as the ratio of the mean square photon noise fluctuations to the average optical power of a light source. In gyroscopic systems, RIN can manifest as angle random walk (ARW). ARW is the noise component affecting optical systems such as the output of a fiber optic gyroscopic system and can affect performance of fiber optic gyroscopic systems.

In interferometric fiber-optic gyroscopes (IFOGs), RIN is typically the dominant source of angle random walk (ARW). It is, therefore, desirable to attenuate, reduce, or eliminate RIN from an optical system such as an IFOG.

In an IFOG, RIN reduction is commonly accomplished through monitoring and digitization of the RIN signal, which is then subtracted from a gyroscopic rate signal in firmware. In some cases, this is known as digital RIN subtraction. Conventional methods of digital RIN reduction require a separate RIN measurement for each gyro. Therefore, individual subtractions are performed for each axis of a gyroscope. Furthermore, digital RIN subtraction occurs after the optical power has passed through coils associated with axes of an IFOG system. After passing through the coils, it can be difficult to differentiate the desired rate signal from the undesired RIN signal, due to spectral filtering caused by the coils. This can lead to difficulty in removing RIN from the optical signal on the backend. This method results in an increase of firmware and inputs and outputs, thereby increasing the likelihood of error. Furthermore, this method of RIN removal can contribute additional components and specificities such as additional analog to digital converters (ADC), digital to analog converters (DAC), among others.

Other systems for RIN reduction in an IFOG system can include analog summation of a RIN signal and one or more rate signals delayed by a coil transmit time. The result of such a summation can yield phase cancellation at the odd harmonics of the RIN signal due to the impact of the transport delay in the frequency domain. This approach, however, increases noise at other frequencies and its efficacy is very dependent on closely-matched RIN and gyro-rate measurements in terms of intensity. Some form of analog gain control would need to be separately implemented for each axis within the system, which would, like the above described systems, further increase additional components and thereby increase size and increase power requirements of the system.

### SUMMARY

To account for these and other technical problems, described herein are concepts, systems and methods for reducing and ideally eliminating relative intensity noise (RIN).

In particular, described herein is analog disturbance rejection loop which reduces and ideally eliminates RIN. The analog disturbance rejection loop includes a detector for detecting an optical signal produced by a light source. An input of the detector corresponds to or is coupled to the input of the analog disturbance rejection loop. An output of the detector is coupled to an input of a transimpedance amplifier and an output of the transimpedance amplifier is coupled to a controller. An output of the controller is configured to be coupled to a control terminal of the light source. The controller is operative to receive signals provided thereto from the transimpedance amplifier and provided a dithered actuation signal at the output thereof. The dithered actuation signal may be provided to the light source to cause the light source to produce intensity fluctuations within the bandwidth in which the light source generates optical power. The so-generated intensity fluctuations having an amplitude substantially equal to (and ideally equal to) the intrinsic RIN but phase-shifted by 180 degrees and thus substantially cancel (and ideally, fully cancel) the light source RIN.

In one embodiment, a device that converts light into an electrical signal (including but not limited to a photodetector, photosensor, photodiode or phototransistor) is disposed at an output of a light source. In one example, the light source is a superluminescent diode (SLD) light source. In response to light incident thereon, the device can convert or transduce optical power incident thereon (or detected thereby) into an electrical signal (e.g. an electrical current or photocurrent) containing both DC and AC signal components. An output of the device is coupled to an input of a transimpedance amplifier (TIA) which converts the photocurrent to a voltage. AC portions of the signal output from the TIA are coupled or otherwise provided to an input of a phase compensation amplifier. This may be accomplished, for example via an AC coupler (e.g. a device which couples or otherwise passes the AC signal component portion of the TIA output signal to the phase compensation amplifier). The device that converts light into an electrical signal, the TIA and the controller thus form an analog disturbance rejection loop around the light source. The analog disturbance rejection loop may also comprises additional components as will be described herein.

In one embodiment, an AC-coupler may be implemented using an active integrator feedback loop disposed about the TIA. Use of an using an active integrator feedback loop allows the TIA to have a relatively high gain without DC saturation. In embodiments, the analog feedback loop AC signal is appropriately conditioned (e.g. level adjusted and/or filtered) and fed into a control loop for the light source.

In embodiments in which the light source is provided as an SLD light source, an appropriately conditioned AC signal can be negatively fed back into a current control loop for the SLD drive.

In embodiments in which the light source is provided as an SLD light source, the AC signal from the transimpedance amplifier can be conditioned (e.g. level adjusted via amplification or attenuation) and/or filtered and negatively fed back into a current control loop for the SLD drive. This results in high-frequency dithering of the current drive of the SLD about a DC setpoint, thereby creating intensity fluctuations at the output of the SLD. As the SLD can be a broadband frequency light source, it can induce RIN along a wide frequency spectrum. Therefore, the SLD is able to generate intensity fluctuations at the variety of frequencies at which the SLD generates optical power. This intensity fluctuation can be substantially equal to (and ideally, equal to) the intensity of the intrinsic RIN but substantially in antiphase (and ideally, in exact antiphase) with the intrinsic RIN. These two opposing noises destructively interfere, substantially cancelling one another out within the loop bandwidth (and ideally cancelling one another out within the loop bandwidth).

In embodiments, the loop bandwidth is made sufficiently wide to encompass many of the first odd harmonics of a gyroscopic coil's eigenfrequency, which, due to the bias modulation intrinsic to IFOG loop closure, are the frequencies at which noise content translates into ARW.

The technical solutions described herein thus reduce the RIN by employing an analog disturbance rejection loop. This analog disturbance rejection loop is around the light source and causes a controller (e.g., an SLD driver in the case where the light source is an SLD) to provide dithered actuation signals which reduce the RIN of the light source. In this way, RIN reduction is performed prior to gyro coils receiving the light rather than upon each separate axis after receiving the light. Furthermore, due to demodulation within a gyro, the only RIN that results in ARW is around odd eigenfrequency harmonics (1st, 3rd, and 5th harmonics, for example). The analog disturbance rejection loop acts as a notch around the lowest odd eigenfrequency harmonics, thereby substantially diminishing RIN's ARW contribution.

The analog disturbance rejection loop concepts, systems and methods described herein thus enable the use of a single RIN measurement point near the light source and largely reduce analog and digital electronics volume and power, while at the same time improving ARW performance. Advantageously, when using three IFOGs in a system with one light source, one analog RIN measurement can be made as opposed to three digitized measurements. Thus, the systems and techniques described herein do not require any digitization of the RIN signal, nor any method of noise subtraction from gyro rate signal(s), either digitally or via an analog method.

In providing an analog disturbance rejection loop for analog RIN cancellation entirely prior to the IFOG coils, the concepts, systems and methods described herein bypass the difficulty and inefficiency of conventional digital RIN subtraction from three channels of differing coil lengths; such nonidealities would otherwise beleaguer systems with three rate axes and a single RIN measurement channel. Furthermore, the concepts, systems and techniques described herein enable fewer analog electronics, ADC channels, digital I/O count, and other components than conventional RIN reduction systems.

At least one aspect of the present disclosure is directed toward a system for reducing relative intensity noise. The system can include a photodetector. The photodetector can detect the relative intensity noise of a light source. The system can include a transimpedance amplifier. The transimpedance amplifier can be part of a feedback loop with the photodetector to generate a first signal. The first signal can be based on the detected relative intensity noise. The system can include a controller. The controller can actuate the light source based upon the first signal to reduce the relative intensity noise.

At least one aspect of the present disclosure is directed towards an analog circuit. The circuit can include a photodetector. The photodetector can detect relative intensity noise of a light source. The circuit can include a transimpedance amplifier. The transimpedance amplifier can be part of a feedback loop with the photodetector to generate a first signal based upon the detected relative intensity noise. The circuit can include a controller. The controller can actuate the light source based upon the first signal to reduce the relative intensity noise.

At least one aspect of the present disclosure is directed towards a method for reducing relative intensity noise. The method can include detecting relative intensity noise (RIN) of a light source. Converting the RIN to an electrical signal. Providing an AC portion of the electrical signal to a light source controller where the AC portion of the electrical signal has an amplitude and phase related to the amplitude and phase of the RIN. Superimposing or otherwise combing the AC signal onto a set point signal for the light source to generate an actuation signal, which when provided to the light source, results in the light source having a reduced RIN.

### BRIEF DESCRIPTION OF THE DRAWINGS

The foregoing and other objects, aspects, features, and advantages of the disclosure will become more apparent and better understood by referring to the following description taken in conjunction with the accompanying drawings. The accompanying drawings are not intended to be drawn to scale. Like reference numbers and designations in the various drawings indicate like elements. For purposes of clarity, not every component may be labeled in every drawing. In the drawings:

FIG. 1A is a block diagram of an exemplary system for reducing relative intensity noise of a light source;

FIG. 1B is a block diagram of an exemplary system for reducing relative intensity noise of a light source;

FIG. 2 is a block diagram of an exemplary system for reducing relative intensity noise of a light source for use in a gyroscopic system;

FIG. 3 is an expanded block diagram of the system for reducing relative intensity noise of a light source;

FIG. 4 is a flow diagram illustrating a method of reducing relative intensity noise of a light source;

FIG. 5A is a plot of current vs. time of intrinsic RIN and RIN with servo ON;

FIG. 5B is a plot of amplitude vs. frequency of an SLD spectrum with servo on and servo off;

FIG. 6A is a plot of Allan Deviation (deg/hr) vs. averaging time (seconds) with no RIN subtraction;

FIG. 6B is a plot of Allan Deviation (deg/hr) vs. averaging time (seconds) with RIN subtraction;

FIG. 7 is a plot of amplitude (left axis) vs. frequency vs. temperature (right axis) illustrating loop gain for an analog system to reduce relative intensity noise of a light source; and

FIG. 8 is a plot of amplitude (left axis) vs. frequency vs. temperature (right axis) for an SLD spectrum with no Servo and SLD spectrum with RINM Servo on.

### DETAILED DESCRIPTION

Before describing the concepts, systems, devices and methods sought to be protected herein, it should be understood that no limitation of the scope of the disclosure is intended by the description of the exemplary embodiments provided herein. Alterations and further modifications of the illustrated features and additional applications of the principles described are to be considered within the scope of the disclosure.

Described herein are concepts, systems and methods for reducing relative intensity noise (RIN).

As will be described in detail below, in embodiments the concepts, systems and techniques described herein enable the use of a single RIN measurement and reduce analog and digital electronics volume and power, while improving ARW performance over conventional systems.

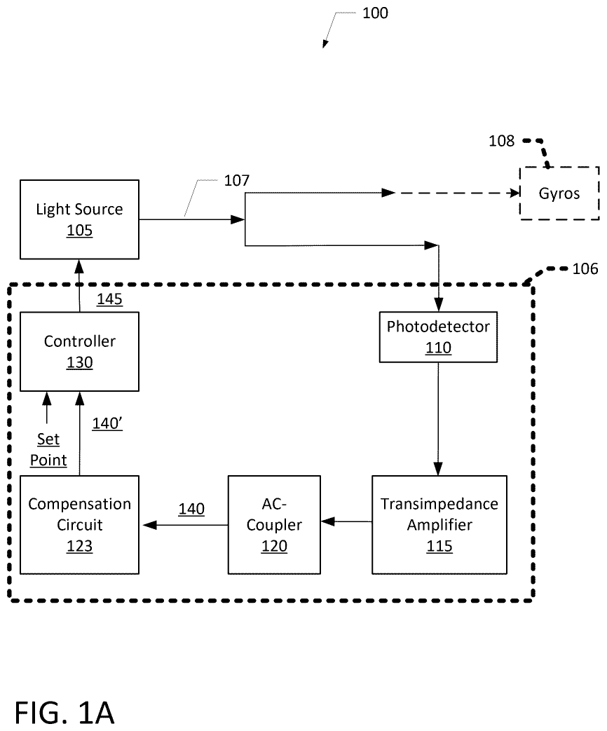

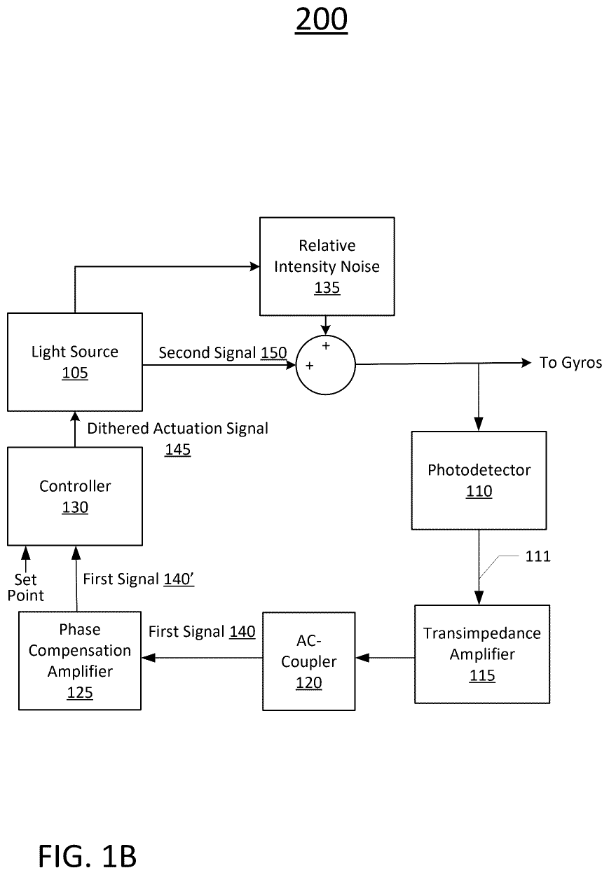

Referring now to FIG. 1A, a system 100 includes light source 105 which outputs an optical light signal (e.g., optical power in the form of a rate signal). The light signal 107 produced by light source 100 inherently includes relative intensity noise (RIN). Thus, light source 100 is inherently a source of RIN. In embodiments, light source 105 may be provided as a high bandwidth light source. In embodiments, light source 105 may be provided as a superluminescent diode (SLD) light source. In embodiments, light source 105 may be provided as a fiber laser diode light source or an FLS light source. The light source 105 can provide optical power to an optical system, such as one or more fiber optic gyros 108 shown in phantom in FIG. 1A. The one or more fiber optic gyros can include an interferometric fiber-optic gyroscope (IFOG).

It should be appreciated that source 105 may be provided as any light source capable of providing a combination power and a spectral bandwidth suitable for the needs of a particular application (e.g. a light source having a wide spectral bandwidth). One of ordinary skill in the art will appreciate how to select a light source to suit the needs of a particular application.

Coupled to light source 105 is an analog disturbance rejection loop 106 which reduces and ideally eliminates RIN generated by light source 105. The analog disturbance rejection loop includes a detector 110 disposed to intercept, sense, detect or otherwise receive light emitted by the light source. Thus, detector detects a light signal produced by light source 105 and provides at an output thereof an electrical signal representative of the light signal emitted or otherwise produced by the light source. Detector 110 may be provided as any device capable of converting light into an electrical signal (including but not limited to a photodetector, photosensor, photodiode or phototransistor). An input of the detector 110 corresponds to or is coupled to the input of the analog disturbance rejection loop.

An output of the detector is coupled to an input of a transimpedance amplifier (TIA) 115. The transimpedance amplifier receives a current signal from the detector and provides a voltage signal at an output thereof. Output signals from the transimpedance amplifier are coupled to an input of a compensation circuit 123. In embodiments in which detector measure both AC and DC components of the light signal, output signals from the transimpedance amplifier are coupled to the input of compensation circuit 123d through an AC coupler 120. Thus, compensation circuit 123 receives signals representing only AC components of the light signal (these AC signal components include or represent the RIN). The AC coupler may be implemented as digital circuitry (e.g. firmware) or as analog circuitry as a combination of analog and digital circuitry. Thus, AC portions of the signal output from the TIA are coupled or otherwise provided to an input of the compensation circuit 123.

Compensation circuit 123 provides amplitude compensation (e.g. amplification and/or attenuation) and phase compensation (e.g., lead-lag compensation) and filtering to signals provided thereto. Compensation circuit 123 stabilizes the analog disturbance rejection loop and band limits the signals provided thereto.

An output of compensation circuit 123 is coupled to an input of a controller 130 and an output of the controller is configured to be coupled to a control terminal of light source 105. The controller is operative to receive signals provided thereto and provides a dithered actuation signal at the output thereof.

In embodiments (e.g., when the light source is provided as an SLD), the controller operates around a set point and attempts to drive the light source at a fixed intensity established by the set point. The compensation circuit provides an input signal (i.e., a feedback signal) corresponding to (or representative of) the AC signal to the controller. Based upon feedback signal 140′, a signal is superimposed over (or otherwise combined with) the set point signal. This superimposing or combining may be accomplished by providing both the set point and feedback signal 140′ to inputs of a summing circuit with the output of the summing circuit coupled to an input of controller 130. The combining may be accomplished via circuitry internal to the controller 130. Thus, the controller set point establishes the intensity of the light signal and the analog disturbance rejection loop 106 operates on the AC portion of the light signal.

The dithered actuation signal may be provided to the light source to cause the light source to produce intensity fluctuations of the light signal within the bandwidth in which the light source generates optical power. The so-generated intensity fluctuations of the light signal (i.e. the light signal fluctuations resultant from the dithered signal) have an amplitude substantially equal to (and ideally equal to) the intrinsic RIN but phase-shifted by 180 degrees. Thus, the intensity fluctuations of the light signal caused by the dithered actuation signal substantially cancel (and ideally, fully cancel) the inherent light source RIN. Thus, the dithered actuation signal causes the light source 105 to output a light signal having a reduced amount of RIN.

In FIG. 1B in which like elements of FIG. 1A are provided having like reference designations, an example system 100 for reducing relative intensity noise of a light source includes a light source 105, a photodetector 110, a transimpedance amplifier 115, an AC-coupler 120, a phase compensation amplifier 125, and a controller 130, among others.

In FIG. 1B, to promote clarity in the description of the concepts described herein, the relative intensity noise inherently generated by light source 105 is pictorially represented by block 135 in FIG. 1B.

In this example embodiment, an analog disturbance rejection loop comprises a photodetector, a transimpedance amplifier, an AC coupler, a phase compensation amplifier and a controller. As described above, the analog disturbance rejection loop operates to provide a dithered actuation signal 145 to reduce (and ideally eliminate) RIN from a light signal provided by light source 105 to gyros or other system components.

The analog disturbance rejection loop functions to reduce the relative intensity noise. In one embodiment the light source is provided as an SLD and the analog disturbance rejection loop produces a high-frequency dithering of a current drive of the SLD about its DC setpoint thus creating an intensity fluctuation of the light signal at the output of the SLD. This intensity fluctuation can destructively interfere with the RIN, cancelling out one another within the loop bandwidth.

In brief overview of the system 100, the photodetector 110 detects the relative intensity noise 135 output by the light source 105. In response to the RIN incident thereon, photodetector 110 produces a photocurrent signal 111 representing the RIN (i.e., the photodetector transduces or converts the detected RIN into a photocurrent signal) and possibly other light signal components (e.g. the photocurrent 111 produced by photodetector 110 contains both DC and AC content).

Photodetector 110 provides the photocurrent signal to an input of transimpedance amplifier 115 (also referred to herein as TIA 115). TIA 115 converts the photocurrent signal provided thereto to a voltage signal and provides the voltage signal at an output thereof.

AC-coupler 120 couples the AC portion of the transimpedance amplifier output signal to an input of phase compensation amplifier 125. AC-coupler 120 can be or may include an active integrator feedback loop around the TIA 115.

The AC-coupler 120 can cause the gain of the TIA 115 to increase without causing DC saturation of the TIA 115. Consequently, a first signal 140 having an amplitude based upon (or commensurate with) the amplitude of the relative intensity noise 135 is coupled from the TIA through the AC coupler to an input of phase compensation amplifier 125. In some cases, the phase compensation amplifier 125 further conditions (e.g. by amplifying, attenuating or otherwise level adjusting and/or filtering) the first signal 140 into the first signal 140′. The first signal 140′ can be negatively fed to the controller 130.

In response to signal 140′ provided thereto, controller 130 generates a dithered actuation signal 145 to provide to the light source 105 based upon the first signal 140 or the first signal 140′.

This dithered actuation signal 145 causes the light source 105 to output a light signal (indicated as second signal 150 in FIG. 1B) having a RIN which effectively cancels the inherent relative intensity noise of the light source (with the inherent represented as signal 135 in FIG. 1B). That is, the RIN generated by the dithered actuation provided to light source and included in signal 150 has an amplitude substantially equal to and in antiphase with the inherent RIN 135 In this way, the dithered RIN in signal 150 substantially cancels the inherent RIN 135. Stated differently, the intensity fluctuation 150 is combined with (e.g. added or subtracted depending upon phasing of signal 150) with the RIN 135. In this way, intensity fluctuation 150 generated by the feedback signal of the analog disturbance rejection loop cancels (or substantially cancels) the RIN 135.

Those of ordinary skill in the art will appreciate that embodiments may comprise additional or alternative components or which omit certain components from those of the example embodiment shown in FIG. 1B, and still fall within the scope of this disclosure.

In greater detail, in some cases, the light source 105 can be a superluminescent diode (SLD) light source or an FLS light source. The light source 105 can provide optical power to an optical system, such as one or more fiber optic gyros. The one or more fiber optic gyros can include an interferometric fiber-optic gyroscope (IFOG). The light source 105 inherently outputs (or generates the relative intensity noise 135. The relative intensity noise 135 is the power noise normalized to the average optical power level output by the light source 105. The relative intensity noise 135 coupled with the desired optical power generated by the light source 105 can cause suboptimal performance of the gyros and associated components if it is not reduced or cancelled.

The photodetector 110 detects the relative intensity noise 135 output by the light source 105. In some cases, the photodetector 110 can detect a total optical power output of the light source 105 and identifies a portion of the total optical power output as the relative intensity noise 135. In detecting the relative intensity noise 135, the photodetector 110 can transduce the relative intensity noise 135 into a photocurrent. In some cases, the photocurrent can include DC components, AC components, or a combination thereof. The photocurrent can be received by the transimpedance amplifier 115.

The transimpedance amplifier 115 can convert the photocurrent to a voltage. The TIA 115 can be coupled with the AC-coupler 120 to provide an AC signal 140 at the output thereof. The TIA 115 can, in some cases, form a feedback loop with the AC-coupler 120 to create the first signal 140. In some cases, the feedback loop is an active integrator feedback loop. In this manner, the gain of the TIA 115 can be increased without causing DC saturation. In embodiments, the AC-coupler may be provided as integral part of the TIA.

The first signal 140 can be further conditioned by the phase compensation amplifier 125. In some cases, the phase compensation amplifier 125 can increase stability of the signal 140 by increasing a phase margin of the TIA 115. In some cases, the phase margin of the system 100 is at least 40 degrees. The phase compensation amplifier 125 can condition the first signal 140 in to the first signal 140′. In some cases, the phase compensation amplifier 125 is optional for conditioning the first signal 140 and may be foregone.

The first signal 140 or the conditioned first signal 140′ can be negatively fed to the controller 130. In some cases, the controller 130 is a driver for the light source 105, such as a driver for an SLC. By providing the first signal 140′, the controller 130 can generate a high-frequency dithering of the current drive of the light source 105 about its DC setpoint. This dithered actuation signal 145 can cause the light source 105 to create an intensity fluctuation output (e.g., the second signal 150). The second signal 150 can be equal to the relative intensity noise 135 but phase-shifted. In some cases, the second signal 150 is phase-shifted by 170-190 degrees. The relative intensity noise 135 and the second signal 150 can destructively interfere, cancelling one another out within the loop bandwidth.

The loop bandwidth can be sufficiently wide to encompass many of the first odd harmonics of the gyroscopic coil's eigenfrequency, which, due to the bias modulation intrinsic to IFOG loop closure, are the frequencies at which noise content translates into ARW.

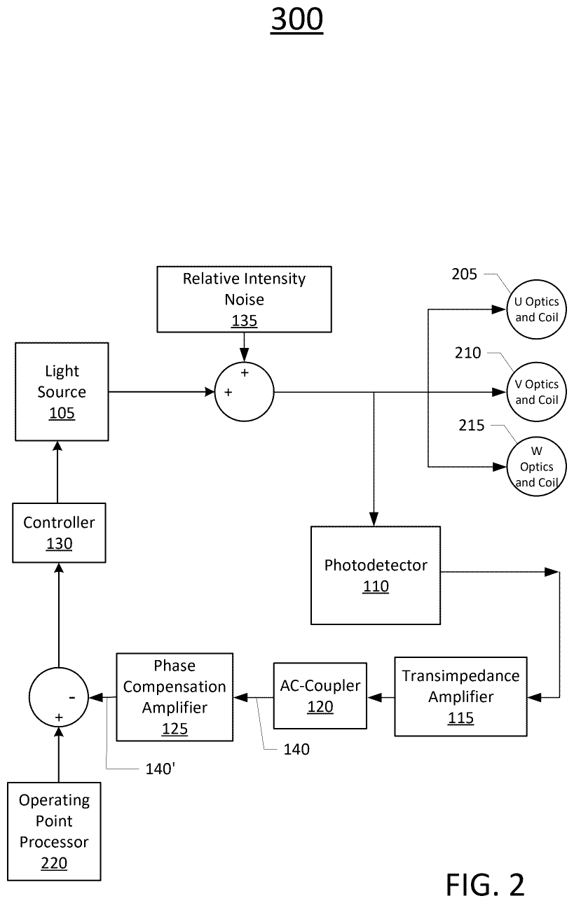

In FIG. 2, a system 200 for reducing relative intensity noise of a light source for use in a gyroscopic system can include any combination of the components described herein, such as in reference to FIG. 1. For example, the system 200 can include a light source 105′, the controller 130, the relative intensity noise 135, the photodetector 110, the transimpedance amplifier 115, the AC-Coupler 120, or the phase compensation amplifier 125, among others. The system can include a digital to analog converter (DAC) 220, a first gyrometer axis 205, a second gyrometer axis 210, and a third gyrometer axis 215.

In some cases, the DAC 220 provides one or more control signals to controller 130. The DAC 220 can, for example, provide a control signal to the controller in response to which the controller actuates the light source 105. In some cases, the signal provided by the DAC 220 is combined with the first signal 140 or in cases when the system includes a phase compensation amplifier, signal 140′ prior to be provided to controller 130. In this manner, the controller 130 can receive instructions on operation of the light source 105 as well as reduce the relative intensity noise 135.

The optical power produced by the light source 105 can be used to operate one or more axes of a gyrometer, such as an IFOG described herein. In some cases, the upon cancelling the relative intensity noise 135, the noise-cancelled optical power of the light source 105 can be transmitted to one or more of the axes of a gyrometer, such as the first gyrometer axis 205, the second gyrometer axis 210, or the third gyrometer axis 215. In some cases, the optical power delivered to the gyrometer axes can drive optical systems and/or coils of the gyrometer.

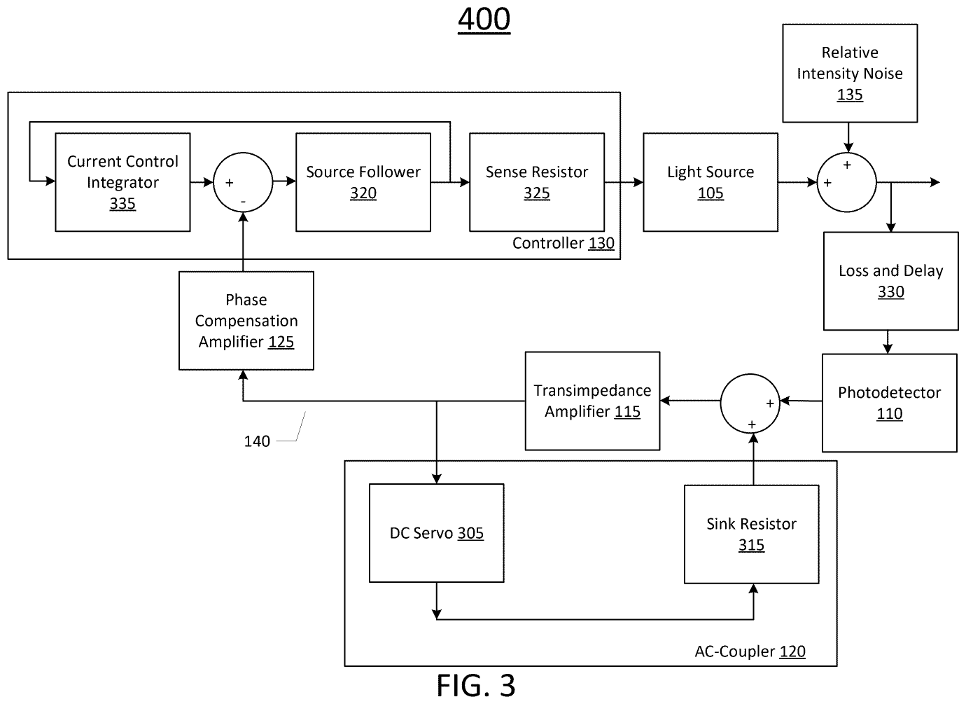

FIG. 3 illustrates an expanded block diagram 300 of the system for reducing relative intensity noise of a light source. The block diagram 300 can include any combination of the components described herein, such as in reference to FIGS. 1A, 1B and 2. For example, the system can include the controller 130, the light source 105, the relative intensity noise 135, the photodetector 110, the transimpedance amplifier 115, the phase compensation amplifier 125, or the AC-coupler 120, among others. The controller 130 can include a current control integrator 335, a source follower 320, or a sense resistor 325, among others. The AC-coupler 120 can include a DC servo 305, a noise rolloff 310, or a sink resistor 315. In some cases, the system can include a source follower 320, a sense resistor 325, or loss and delay 330.

The AC-coupler 120 can include the DC servo 305. The DC servo 305 can provide feedback and closed-loop control for the loop created by the transimpedance amplifier 115 and the AC-coupler 120. The AC-coupler 120 can also include the filter circuitry (not explicitly shown in FIG. 3) to isolate a frequency or set of frequencies at which the relative intensity noise 135 occurs. The AC-coupler 120 can include a sink resistor 315. The sink resistor 315 can dissipate excessive heat in the system and convert a signal to a current for input into the transimpedance amplifier 115. In this manner, the relative intensity noise 135 can be translated by the transimpedance amplifier 115 to provide the first signal 140 to the phase compensation amplifier 125 or the controller 130.

The controller 130 can include the current control integrator 325, the source follower 320, and the sense resistor 325 to provide a control signal (including, for example, the dithered actuation signal 145) to the light source 105.

In some cases, the system can include the loss and delay circuitry 330. The loss and delay circuity 330 can include a fiber insertion loss and/or a transport delay. In some cases, a fiber insertion loss can be between 10-20 dB and is intrinsic to the system. In some cases, the transport delay can be between 2-8 ns and is intrinsic to the system.

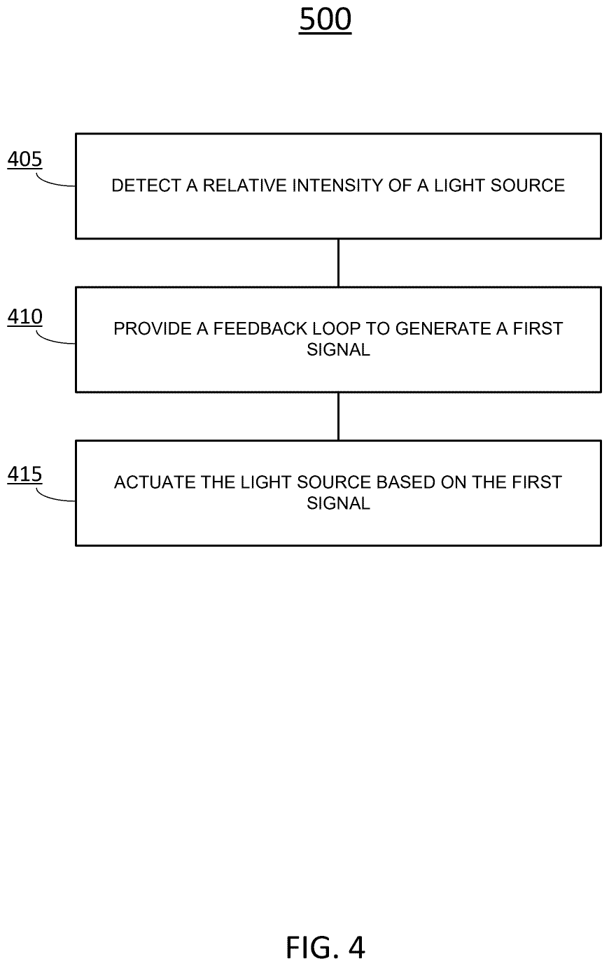

FIG. 4 illustrates a flow of a method 400 for reducing relative intensity noise of a light source. The method 400 includes Acts 405-415. The method 400 can include fewer or more acts than those depicted, and in any order or sequence. At Act 405, the system detects a relative intensity of a light source. In some cases, a photodetector can detect the relative intensity of the light source.

At Act 410, the system can provide a feedback loop to generate a first signal. In some cases, the transimpedance amplifier creates a feedback loop with the photodetector to generate the first signal. In some cases, the transimpedance amplifier creates a feedback loop with the AC-coupler to produce the first signal. In some cases, the transimpedance amplifier creates the first signal based on inputs from the AC-coupler and/or the photodetector.

The system can provide the first signal to the controller. In some cases, the photodetector, the transimpedance amplifier, and the light source form an analog disturbance rejection loop around the controller to reduce the relative intensity noise. In some cases, the first signal is generated by a gain circuit created with the transimpedance amplifier. In some cases, prior to providing the first signal to the controller, a phase compensation amplifier conditions the first signal.

At Act 415, the system can actuate the light source based on the first signal. The controller can generate a dithered actuation signal based on the first signal. The controller can actuate the light source based on the dithered actuation signal. In this manner, the controller can actuate the light source based on the first signal. The light source can generate, with the dithered actuation signal, a second signal which negatively interferes with the relative intensity noise.

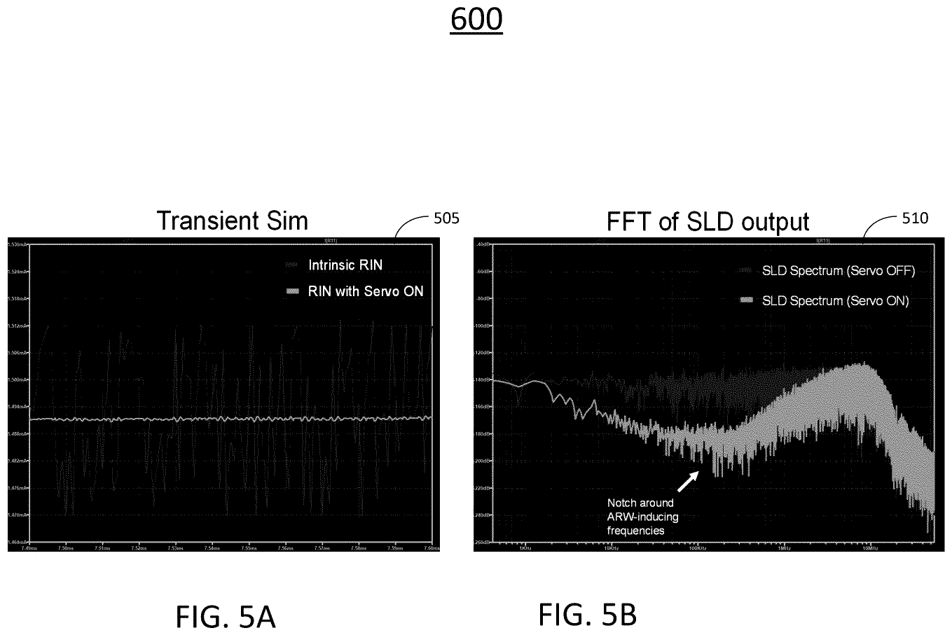

FIG. 5 illustrates a diagram 500 of results for a system to reduce relative intensity noise of a light source. The diagram 500 includes transient results 505 and frequency results 510. The transient results 505 illustrate a reduction in relative intensity noise with operation of the technological solutions described herein as compared to a system without such technological solutions implemented. The frequency results 510 illustrate a notch around the lowest odd eigenfrequency harmonics with operation of the technological solutions described here as compared to a system without such technological solutions implemented. The notch at these harmonics can substantially (as seen in 510) diminish the relative intensity noise.

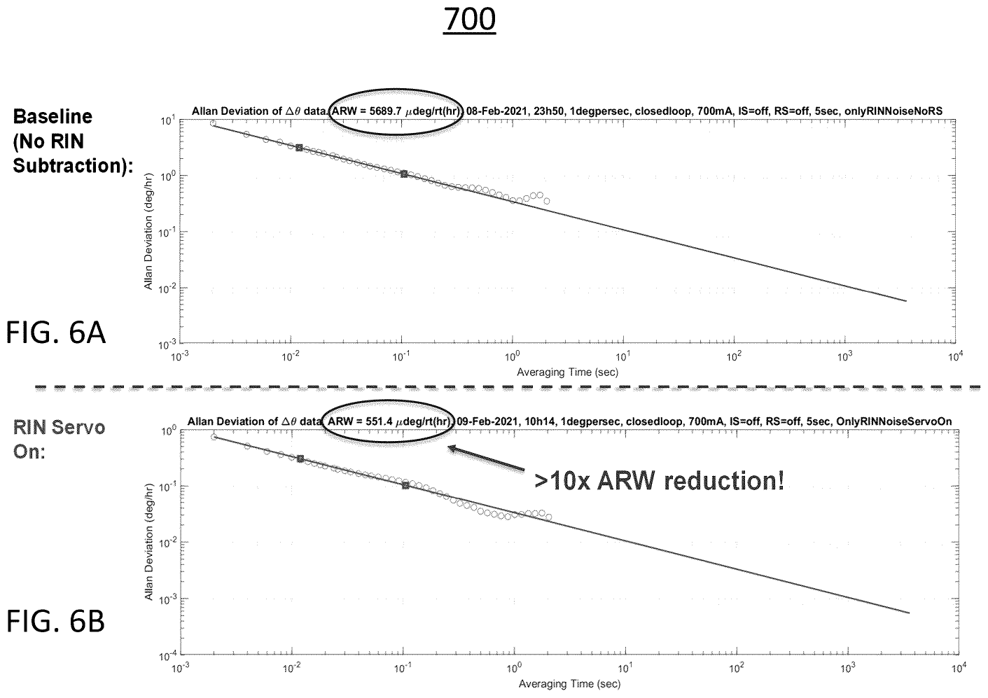

FIG. 6 illustrates a diagram 600 of improvement in relative intensity noise through the systems and methods described herein. As shown in FIG. 6, an improvement of ARW is shown when implementing the technological solutions described here.

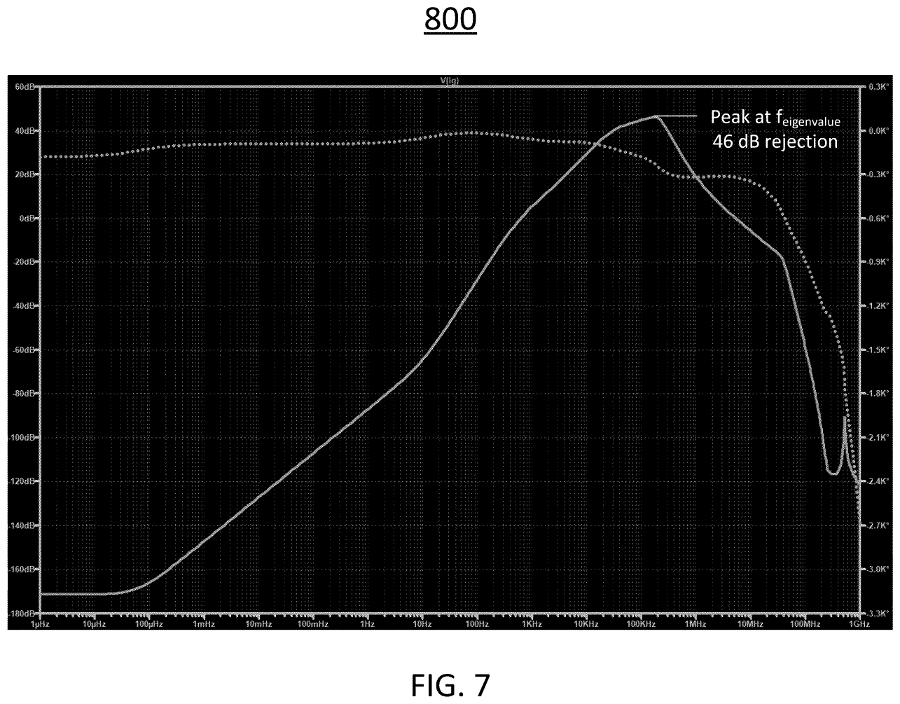

FIG. 7 illustrates a graph 700 of loop gain for an analog system to reduce relative intensity noise of a light source. The graph 700 illustrates a peak at eigenvalue frequencies of the system, showing a nearly 46 dB rejection of relative intensity noise.

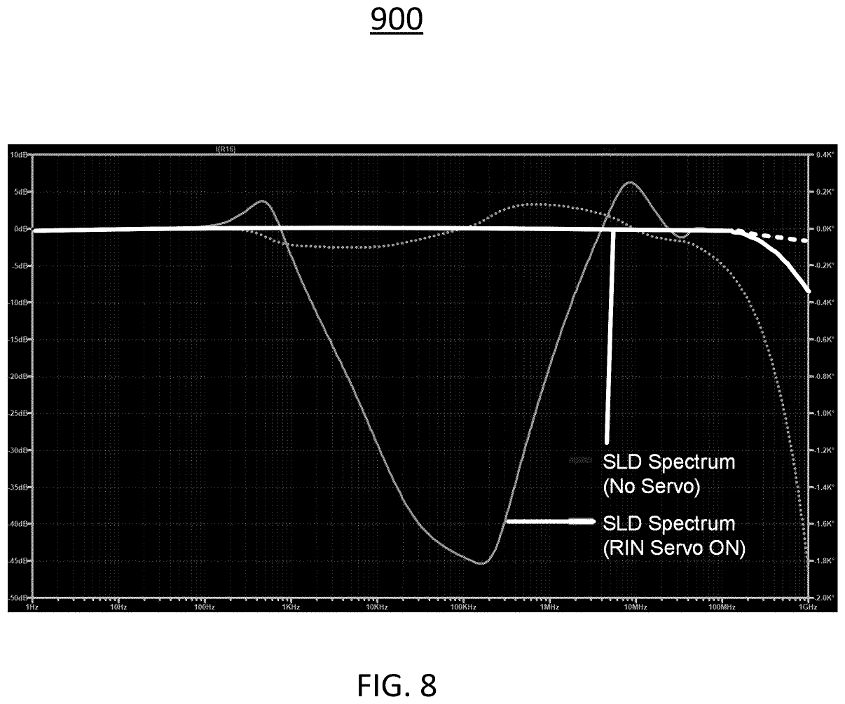

FIG. 8 illustrates a diagram 800 of relative intensity noise rejection through the systems and methods described herein. The diagram 800 depicts a closed-loop gain. The diagram 800 depicts how the loop around the controller as described herein can create a notch filter around lowest odd eigenfrequency harmonics, thereby providing RIN rejection. The diagram 800 shows a comparison of frequencies of an output of optical power of the light source (e.g., the SLD) with and without the technological solutions described herein.

Using the technical solution described herein, relative intensity noise of an optical system can be reduced. The analog circuit described herein enables the reduction of relative intensity noise at the source without the need for digital processing correction at the back end. This enables a reduction of the RIN prior to transmitting optical power to one or more axes of a gyroscope. In this manner, size, error, and power consumption can be reduced.

1. A system to reduce relative intensity noise, comprising:
a photodetector configured to detect the relative intensity noise of a light source;
a transimpedance amplifier configured to provide a feedback loop with the photodetector to generate a first signal based on the detected relative intensity noise; and
a controller configured to actuate the light source based on the first signal to reduce the relative intensity noise.

2. The system of claim 1, wherein the photodetector, the transimpedance amplifier, and the light source form an analog disturbance rejection loop around the controller to reduce the relative intensity noise.

3. The system of claim 1, wherein the light source is configured to generate, responsive to being actuated by the controller based on the first signal, a second signal, wherein the second signal is equal in amplitude to the relative intensity noise and phase shifted by 170-190 degrees from the relative intensity noise.

4. The system of claim 1, comprising a gain circuit configured to provide the first signal to the controller.

5. The system of claim 1, wherein to actuate the light source based on the first signal,
the controller is configured to:
generate a dithered actuation signal based on the first signal; and
provide the dithered actuation signal to the light source to cause the light source to provide a second signal which destructively interferes with the relative intensity noise.

6-12. (canceled)

13. The method of claim 22, wherein generating the actuation signal comprises generating a signal equal in amplitude to the relative intensity noise and phase shifted by 170-190 degrees from the relative intensity noise.

14-16. (canceled)

17. The system of claim 21 further comprising a phase compensation circuit having an input coupled to the output of the transimpedance amplifier and having an output coupled to the input of the controller.

18. The system of claim 21 further comprising an AC-coupler circuit coupled to the output of the transimpedance amplifier and configured to subtract a DC component of a signal at an output of the transimpedance amplifier.

19. The system of claim 21 wherein the controller comprises:
a current control integrator; and
a source follower circuit coupled in a feedback loop with the current control integrator with an output of the source follower circuit configured to be coupled to an input of the light source.

20. A system comprising:
a light source having a control terminal and a light port; and
an analog disturbance rejection loop having an input coupled to the light source light port and having an output coupled to the light source control terminal, the analog disturbance rejection loop operative to receive at least a portion of a light signal from the light source light port and in response thereto provide an actuation signal to the light source control terminal to reduce relative intensity noise of the light source.

21. The system of claim 20, wherein the analog disturbance rejection loop comprises:
a photodetector having an input corresponding to the input of the analog disturbance rejection loop and having an output;
a transimpedance amplifier having an input coupled to the output of the photodetector and having an output; and
a controller having an input coupled to the output of the transimpedance amplifier and having an output coupled to the control terminal of the light source, the controller operative to receive signals provided thereto from the transimpedance amplifier and provided a dithered actuation signal at the output thereof.

22. A method for reducing relative intensity noise, comprising:
sensing relative intensity noise of a light source and providing an analog current signal in response thereto;
converting the analog current signal to an analog voltage signal
providing an ac component of the analog voltage signal to a controller;
in response to receiving the ac component of the analog voltage signal, generating an actuation signal; and
providing the actuation signal to a control terminal of the light source.

23. The method of claim 22 wherein sensing relative intensity noise of a light source and providing an analog current signal in response thereto comprises sensing relative intensity noise of a light source with a photodetector and generating a photocurrent in response thereto.

24. The method of claim 23 wherein converting the analog current signal to an analog voltage signal comprises converting the photocurrent to an analog voltage signal.

25. The method of claim 24 wherein converting the photocurrent to an analog voltage signal comprises providing the photocurrent to an input of a transimpedance amplifier.

26. The method of claim 22 wherein generating an actuation signal comprises generating a dithered light source actuation signal which reduces relative intensity noise of the light source.

27. The method of claim 26 wherein providing an ac component of an output signal of the transimpedance amplifier to a controller comprises substantially eliminating a dc component of the output signal of the transimpedance amplifier.
